(19) United States
(12) Patent Application Publication
(10) Pub. No.: US 2013/0240995 A1
(43) Pub. Date: Sep. 19, 2013

(54) THIN-FILM TRANSISTOR ARRAY SUBSTRATE AND MANUFACTURING METHOD THEREOF

(71) Applicant: Jinlei Li, Shenzhen (CN)

(72) Inventor: Jinlei Li, Shenzhen (CN)

(73) Assignee: SHENZHEN CHINA STAR OPTOELECTRONICS TECHNOLOGY CO., LTD, Shenzhen (CN)

(21) Appl. No.: 13/514,979

(22) PCT Filed: Mar. 26, 2012
(86) PCT No.: PCT/CN12/73013

§ 371 Date: Jun. 9, 2012

(30) Foreign Application Priority Data
Mar. 19, 2012 (CN) 201210072203.2

(51) Int. Cl. H01L 27/088; H01L 21/28

(52) U.S. Cl. 257/368; 438/652; 257/E27.06; 257/E21.158

(57) ABSTRACT

The present invention discloses a thin-film transistor array substrate and a manufacturing method thereof. The thin-film transistor array substrate has scanning lines and data lines. The scanning lines are formed by a first metallic layer. The data lines are formed by a second metallic layer. Each of the first and the second metallic layers has a multilayer structure. The multilayer structure includes a primary electrically conductive layer and at least one blocking layer. The primary electrically conductive layer has a restraining metallic layer mounted inside and having a melting point higher than the melting point of the primary electrically conductive layer.

### BACKGROUND OF THE INVENTION

1. Field of the Invention

The present invention relates to a field of liquid crystal display technology, especially to a thin-film transistor array substrate and a manufacturing method thereof.

2. Description of the Related Art

In the field of liquid crystal display technology, a thin-film transistor liquid crystal display (TFT-LCD) is getting more and more applications because of having advantages of high resolution, low power consumption, light weight, radiation free and having various sizes.

A thin-film transistor liquid crystal display device is generally constructed by a thin-film transistor (TFT) array substrate and a color filter (CF) substrate, wherein liquid crystal material is filled between the substrates through a liquid crystal cell manufacturing process and then the substrates and other related components are assembled together by module factories. During the process of manufacturing a thin-film transistor array substrate, a plurality of film-forming processes, such as sputtering or chemical vapor deposition, are required. And each time when a film is formed, there are processes, such as coating, exposure, development and etching, to be performed.

Take sputtering coating as an example, sputtering coating is to use a sputtering method to deposit metallic films and Indium Tin Oxide (ITO) films, and then perform a photolithography process to form the data lines, scanning lines and pixel electrodes. The data lines are used to transmit voltage signals including gray scale information; the scanning lines are used to transmit voltage signals for turning on/off a thin-film transistor. The signal lines and the scanning lines generally are formed by metals or alloys having lower electric resistivity.

In the conventional technologies, the size of a thin-film transistor liquid crystal display device is continuously increasing. Since a certain light transmittance is required, the widths of the scanning lines and data lines for connecting thin-film transistors cannot be increased without limit, and only increasing the lengths of the scanning lines and data lines can be taken into consideration. However, increasing the lengths of the scanning lines and the data lines leads to the increase of resistance of the lines, and the increase of resistance will enormously lower the transmitting speed of signals, and further lower the display quality.

Besides, after the photolithography process for forming the scanning lines, a process of chemical vapor deposition with temperature reaching 350° C. is required to form the active layer of the thin-film transistor. Therefore, in the meantime, the metallic layer that forms the scanning lines must be heat resistant at a high temperature of 350° C.

In conventional technologies, using copper or copper alloy to form the scanning lines and the data lines may, in a certain extent, solve the problem of increasing of electric resistance and the requirement of high-temperature resistance, but the material cost of copper is high and the manufacturing process has difficulty in etching copper layers.

To avoid the foregoing problem caused by using copper as the coating material, another conventional technology is to use a multilayer structure including a molybdenum layer and an aluminum layer stacked together or including a molybdenum layer, an aluminum layer and another molybdenum layer stacked together.

For example, in a metallic layer having a molybdenum layer and an aluminum layer stacked together, since the electric resistivity of aluminum is lower than the electric resistivity of molybdenum, the aluminum layer is used as a main electrically conductive layer. But the melting point of aluminum is lower (about 660° C.), in the high-temperature environment during chemical vapor deposition, aluminum atoms will push against each other, once reaching certain strain, the aluminum layer will be deformed to have hillocks and then result in a short circuit between the scanning lines and the data lines. The melting point of molybdenum is relatively higher (above 2000° C.), and the molybdenum layer has pillar-shaped crystalline structures which can restrain the molybdenum layer from forming hillocks in high-temperature environment. Therefore, a layer made of molybdenum is usually used as a blocking layer or a passivation layer for the aluminum layer.

For large-sized thin-film transistor liquid crystal displayer devices, in order to reduce the resistivity of the scanning lines and data lines, a conventional skill is increasing the thickness of the aluminum layer. However, when the thickness of the aluminum layer is increased, in the high-temperature environment during chemical vapor deposition, the aluminum layer forms hillocks because of the high-temperature, and the hillocks may penetrate through the molybdenum layer under a worst case scenario and lead to short circuit occurred between the gate, the source and the drain of the thin-film transistor and then affect screen display quality.

Besides, after the foregoing metallic layer structure having the molybdenum layer and the aluminum layer stacked together are etched to form the data lines or the scanning lines, the cross-section of the etched metallic layer has a tapered shape from bottom to top for subsequent film forming processes. In the multilayer structure including a molybdenum layer and an aluminum layer stacked together or including a molybdenum layer, an aluminum layer and another molybdenum layer stacked together, when the thickness of the aluminum layer is increased, the aluminum layer increases in volume and occupies more space; and in the accompany wet etching process, galvanic corrosion may occur due to the oxidation characteristic difference between aluminum and molybdenum and then cause the etching speed of molybdenum to be slower than the etching speed of aluminum. Therefore, the molybdenum layer at top becomes protruded out from the aluminum layer. In the subsequent film forming processes, the material for forming a film will be affected by the protruded molybdenum layer and cannot completely adhere at an etching edge of the metallic layer and thereby cause abnormal production characteristic.

In conclusion, the increase of the thickness of aluminum layer may easily result in hillocks in high-temperature environment during chemical vapor deposition process, and result in out-protruded molybdenum layer by the electro-chemical effect occurred between aluminum and molybdenum during wet etching process.

### SUMMARY OF THE INVENTION

An object of the present invention is to provide a thin-film transistor array substrate to solve a technical problem that the increase of the thickness of aluminum layer in prior art easily results in hillocks in high-temperature environment during chemical vapor deposition process, and easily results in an out-protruded molybdenum layer by the electro-chemical effect occurred between aluminum and molybdenum during wet etching process.

In order to solve the foregoing problem, the present invention provides a thin-film transistor array substrate having multiple scanning lines, data lines and thin-film transistors. Each of the thin-film transistor includes a gate, a source and a drain; the scanning lines and the gate are formed by a first metallic layer; the data lines, the source and the drain are formed by a second metallic layer; the first metallic layer and the second metallic layer each has a multilayer structure; the multilayer structure includes a primary electrically conductive layer and at least one blocking layer, wherein

the primary electrically conductive layer a restraining metallic layer mounted therein and having a melting point higher than a melting point of the primary electrically conductive layer; and the restraining metallic layer has a thickness ranged between 0.5 nm and 2 nm.

In the thin-film transistor array substrate of the present invention, the primary electrically conductive layer is formed by aluminum; and the blocking layer and the restraining metallic layer are formed by molybdenum.

In the thin-film transistor array substrate of the present invention, the first metallic layer includes a first primary electrically conductive layer and a first blocking layer; the first primary electrically conductive layer has a first restraining metallic layer mounted therein; the second metallic layer includes a second blocking layer, a second primary electrically conductive layer and a third blocking layer; and the second primary electrically conductive layer has a second restraining metallic layer mounted therein.

Another object of the present invention is to provide a thin-film transistor array substrate so as to solve a technical problem that the increase of the thickness of aluminum layer in prior art easily results in hillocks in high-temperature environment during chemical vapor deposition process, and easily results in an out-protruded molybdenum layer by the electro-chemical effect occurred between aluminum and molybdenum during wet etching process.

In order to solve the foregoing problem, the present invention provides a thin-film transistor array substrate having multiple scanning lines and data lines. The scanning lines are formed by a first metallic layer and the data lines are formed by a second metallic layer. The first and the second metallic layers each has a multilayer structure. The multilayer structure includes a primary electrically conductive layer and at least one blocking layer. The primary electrically conductive layer has a restraining metallic layer mounted therein and having a melting point higher than a melting point of the primary electrically conductive layer.

In the thin-film transistor array substrate of the present invention, the thin-film transistor array substrate further has a thin-film transistor; the thin-film transistor includes a gate, a source and a drain; the gate is formed by the first metallic layer; and the source and the drain are formed by the second metallic layer.

In the thin-film transistor array substrate of the present invention, the restraining metallic layer has a thickness ranged between 0.5 nm and 2 nm.

In the thin-film transistor array substrate of the present invention, the primary electrically conductive layer is formed by aluminum; and the blocking layer and the restraining metallic layer are formed by molybdenum.

In the thin-film transistor array substrate of the present invention, the first metallic layer includes a first primary electrically conductive layer and a first blocking layer; and the first primary layer has a first restraining metallic layer mounted therein;

the second metallic layer includes a second blocking layer, a second primary electrically conductive layer and a third blocking layer, and the second primary electrically conductive layer has a second restraining metallic layer mounted therein.

Another object of the present invention is to provide a manufacturing method of a thin-film transistor array substrate so as to solve a technical problem that the increase of the thickness of aluminum layer in prior art easily results in hillocks in high-temperature environment during chemical vapor deposition process, and easily results in an out-protruded molybdenum layer by the electro-chemical effect occurred between aluminum and molybdenum during wet etching process.

In order to solve foregoing problem, the present invention provides a manufacturing method of the thin-film transistor array substrate, and the manufacturing method includes steps of:

providing a glass substrate, forming a first metallic layer on the glass substrate and performing an etching treatment to the first metallic layer to form multiple scanning lines;

orderly depositing an insulating layer and a semiconductor layer on the first metallic layer;

forming a second metallic layer on the semiconductor layer and performing an etching treatment to the second metallic layer to form multiple data lines; and

depositing a passivation layer on the second metallic layer and forming a transparent electrode layer on the passivation layer; wherein

the first metallic layer and the second metallic layer each has a multilayer structure; the multilayer structure includes a primary electrically conductive layer and at least one blocking layer; the primary electrically conductive layer has a restraining metallic layer mounted therein and having a melting point higher than a melting point of the primary electrically conductive layer.

In the manufacturing method of the thin-film transistor array substrate of the present invention, while performing the etching treatment to the first metallic layer to form the scanning lines, also form a gate of a thin-film transistor; and

while performing the etching treatment to the second metallic layer to form the data lines, also form a source and a drain of the thin-film transistor.

In the manufacturing method of the thin-film transistor array substrate of the present invention, the step of forming the first metallic layer on the glass substrate specifically comprises steps of:

forming a first-portion aluminum layer by sputtering; forming a molybdenum layer on the first-portion aluminum layer by sputtering; forming a second-portion aluminum layer on the molybdenum layer by sputtering to construct the first metallic layer.

In the manufacturing method of the thin-film transistor array substrate of the present invention, the step of forming the second metallic layer on the semiconductor layer specifically comprises steps of:

forming a molybdenum layer on the semiconductor layer by sputtering to form a second blocking layer;

forming a first-portion aluminum layer on the second blocking layer by sputtering; forming a molybdenum layer on the first-portion aluminum layer by sputtering; forming a second-portion aluminum layer on the molybdenum layer by sputtering to construct the second primary electrically conductive layer; and

forming another molybdenum layer on the second primary electrically conductive layer by sputtering to form a third blocking layer.

In the manufacturing method of the thin-film transistor array substrate of the present invention, the restraining metallic layer has a thickness ranged between 0.5 nm and 2 nm.

Comparing with the conventional technology, the present invention can restrain deformation of aluminum layer under high-temperature environment by adding a restraining metallic layer (for example, a molybdenum layer) in the aluminum layer of the aluminum-and-molybdenum structure, and can also restrain the protrusion of the molybdenum layer caused by chemical reaction between the aluminum layer and the molybdenum layer, and thereby the present invention can ensure normal characteristics of the products and enhance image display quality.

In order to make the contents of the present invention to be more easily understood, the preferred embodiments of the present invention are described in detail in cooperation with accompanying drawings as follows:

### BRIEF DESCRIPTION OF THE DRAWINGS

FIG. 1 is a top view of an embodiment of a thin-film transistor array substrate in accordance with the present invention;

FIG. 2 is a cross-sectional view taken along the line A-A′ in FIG. 1;

FIG. 3 is a cross-sectional view taken along the line B-B′ in FIG. 1;

FIG. 4 is a cross-sectional view taken along the line C-C′ in FIG. 1; and

FIG. 5 is a flow chart of a manufacturing method of the thin-film transistor array substrate of the present invention.

### DETAILED DESCRIPTION OF THE PREFERRED EMBODIMENTS

Following description of each embodiment is referring to the accompanying drawings so as to illustrate practicable specific embodiments in accordance with the present invention.

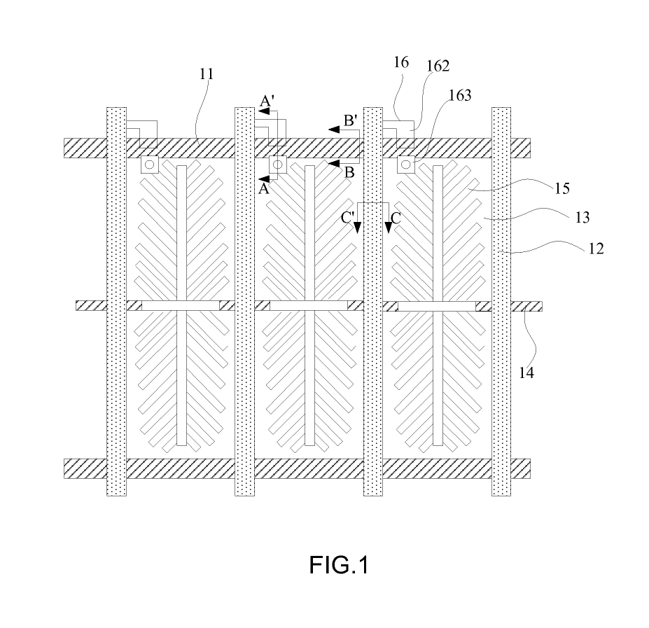

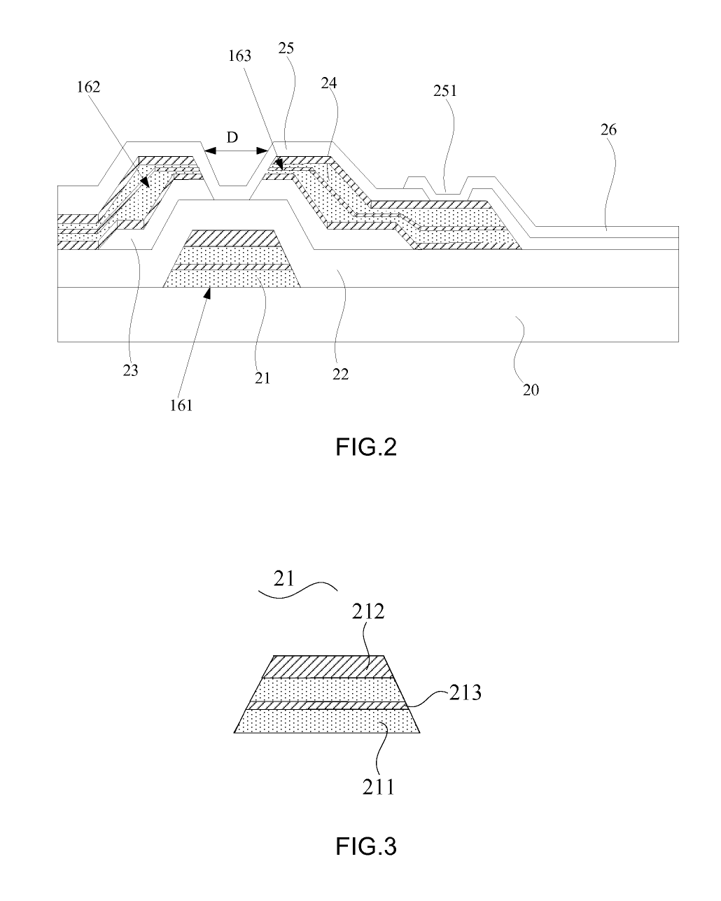

With reference to FIG. 1, FIG. 1 is a top view of an embodiment of a thin-film transistor array substrate in accordance with the present invention. FIG. 2 is a cross-sectional view taken along the line A-A′ in FIG. 1.

With reference to FIGS. 1 and 2, the thin-film transistor array substrate comprises multiple scanning lines 11, multiple data lines 12, wherein the scanning lines 11 and the data lines 12 are crossed with each other and are perpendicular to each other. A crossing area defines a pixel 13. The pixel 13 includes a common electrode 14 and a pixel electrode 15. The pixel electrode 15 has a plurality of comb-shaped structures.

The thin-film transistor array substrate further comprises multiple thin-film transistors (TFT) 16. The thin-film transistors 16 each corresponds to one of the pixels 13. Each of the thin-film transistors 16 includes a gate 161, a source 162 and a drain 163, wherein the gate 161 is a portion of one of the scanning lines 11, the source 162 is connected to one of the data lines 12, the drain 163 has a through hole 251, and the through hole 251 is connected to the corresponding pixel electrode 15.

With further reference to FIG. 2, a first metallic layer 21 is formed on a glass substrate 20. After the first metallic layer 21 is etched, the gate 161 is formed and is trapezoid-shaped so as to facilitate the attachment of an insulating layer 22 and a semiconductor layer 23.

The insulating layer 22 and the semiconductor layer 23 are deposited on the gate 161. A second metallic layer 24 is deposited on the semiconductor layer 23. The second metallic layer 24 has a passivation layer 25 formed there on. A cross-section of the second metallic layer 24 is taper-shaped after being etched so as to facilitate the attachment of the passivation layer 25.

A transparent electrode layer 26 is formed on the passivation layer 25. A center of the passivation layer 25 has a through hole 251 formed therethrough (corresponding to the position of the drain 163 in FIG. 1), and the transparent electrode layer 26 is connected to the second metallic layer 24 via the through hole 251.

Please refer to FIGS. 1, 2 and 3, wherein FIG. 3 is a cross-sectional view taken along the line B-B′ in FIG. 1.

The first metallic layer 21 is etched to form the scanning lines and the gate 161. The first metallic layer 21 includes a first primary electrically conductive layer 211 and a first blocking layer 212 being stacked on the first primary electrically conductive layer 211.

The first primary electrically conductive layer 211 is preferably an aluminum layer. The first blocking layer 212 is preferably a molybdenum layer, and also can be a metallic layer made of other materials not specifically enumerated herein.

In this embodiment, the first primary electrically conductive layer 211 further has a first restraining metallic layer 213 mounted therein. The first restraining metallic layer 213 is preferably a molybdenum layer, and is used to restrain the first primary electrically conductive layer 211 from deforming under a high-temperature environment, and is used to restrain the protrusion of the first blocking layer 212 caused by the chemical reaction between the first primary electrically conductive layer 211 and the first blocking layer 212. The first restraining metallic layer 213 may be formed by other metal materials with high melting point which are not specifically enumerated herein, as long as the materials can also achieve the above-mentioned beneficial effects.

Herein, the first restraining metallic layer 213 has a thickness ranged preferably between 0.5 nm and 2 nm.

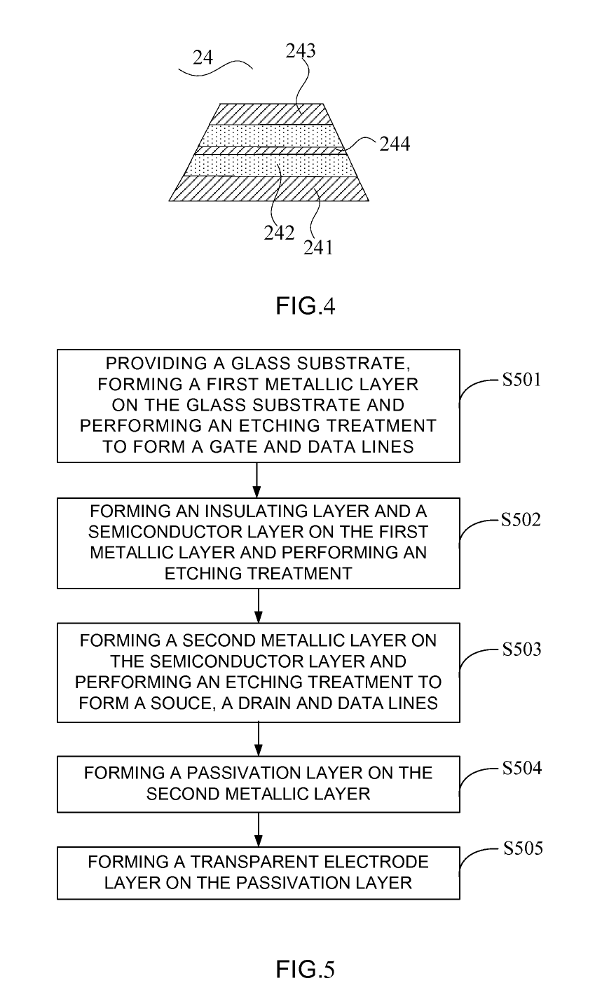

Please refer to FIGS. 1, 2 and 4, wherein FIG. 4 is a cross-sectional view taken along the line C-C′ in FIG. 1.

The second metallic layer 24 is etched to form the data lines 12, the source 162 and the drain 163. The second metallic layer 24 includes a second blocking layer 241, a second primary electrically conductive layer 242 and a third blocking layer 243.

The second blocking layer 241 and the third blocking layer 243 are preferably molybdenum layers, and the second primary electrically conductive layer 242 is preferably an aluminum layer.

In the present embodiment, the second primary electrically conductive layer 242 further has a second restraining metallic layer 244 mounted therein. The second restraining metallic layer 244 is preferably a molybdenum layer and is used to restrain the deformation of the second primary electrically conductive layer 242 under high-temperature environment, and is used to restrain the protrusion of the third blocking layer 243 caused by the chemical reaction occurred between the second primary electrically conductive layer 242 and the third blocking layer 243. The second restraining metallic layer 244 may also be formed by other metallic materials with high melting point that are not specifically enumerated herein, as long as the materials can also achieve the above-mentioned beneficial effects.

Herein, the second restraining metallic layer 244 has a thickness ranged between 0.5 nm and 2 nm.

With reference to FIG. 5, FIG. 5 is a flow chart of a manufacturing method of the thin-film transistor array substrate of the present invention. The structure of the thin-film transistor array substrate of the present invention is described in detail thereinafter in cooperation with FIGS. 1 to 5.

In a step S501, provide a glass substrate 20; use magnetron sputtering to deposit a first metallic layer 21 on the glass substrate 20; and perform an etching treatment to the first metallic layer 21 to form the scanning lines 11 and the gate 161.

Herein, while forming the first metallic layer 21, a first-portion aluminum layer is first sputtered on the glass substrate 20. Specifically, place the glass substrate 20 that has been washed into a magnetron sputtering machine table; then adjust the position of the glass substrate 20 to a corresponding position facing an aluminum target inside the machine table; then set a film formation power between 40 KW and 70 KW; then set a sputtering time between 28 seconds and 49 seconds; and set the gas pressure between 0.05 Pa and 0.3 Pa inside a sputtering chamber.

After forming the first-portion aluminum layer, then form a thin molybdenum layer (i.e. the first restraining metallic layer 213 with a thickness ranged between 0.5 nm and 2 nm) on the first-portion aluminum layer by sputtering. Specifically, adjust the glass substrate 20 to a position facing molybdenum target inside the machine table; then set the gas pressure between 0.05 Pa and 0.3 Pa inside the sputtering chamber; set a film formation power between 5 KW and 20 KW; and set a sputtering time between 1 and 4 seconds.

After forming the above-mentioned molybdenum layer, continue to forming a second-portion aluminum layer on the molybdenum layer by sputtering. Specifically, adjust the glass substrate 20 to a position facing aluminum target inside the machine table; then set the gas pressure between 0.05 Pa and 0.3 Pa inside the sputtering chamber; set the film-forming power between 40 KW and 70 KW; and set the sputtering time between 28 and 49 seconds.

As a result, the first primary electrically conductive layer 211 having the first restraining layer 213 formed therein is constructed.

After that, continue to form another molybdenum layer on the first primary electrically conductive layer 211 by sputtering to form the first blocking layer 212. Specifically, adjust the glass substrate 20 having the first primary electrically conductive layer 211 formed thereon to a corresponding position facing molybdenum target in the machine table; set the gas pressure between 0.05 Pa and 0.3 Pa; set the film-forming power between 50 KW and 65 KW; and set the sputtering time between 6 and 10 seconds.

The first primary electrically conductive layer 211 and the first blocking layer 212 construct the first metallic layer 21, wherein the first primary electrically conductive layer 211 has the first restraining metallic layer 213 formed therein.

In a step S502, use plasma-enhanced chemical vapor deposition technology to deposit the insulating layer 22 and the semiconductor layer 23 on the first metallic layer 21.

In this step, even though the plasma-enhance chemical vapor deposition is perform under a higher temperature, the first primary electrically conductive layer 211 can be prevented from forming hillocks since the first primary electrically conductive layer 211 of the first metallic layer 21 has the first restraining metallic layer 213 formed inside, thereby normal image display of liquid crystal display is ensured.

In a step of S503, continue to form the second metallic layer 24 on the semiconductor layer 23 by sputtering, and perform an etching treatment to the second metallic layer 24 to form the source 162, the drain 163, the data lines 12 and a slot D.

In the process of forming the second metallic layer 24, first form a molybdenum layer on the semiconductor layer 23 by sputtering to form the second blocking layer 241. Specifically, wash the glass substrate 20 that has finished the photolithography process for forming the semiconductor layer 23, and then place glass substrate 20 into the magnetron sputtering machine table; and then adjust the glass substrate 20 to a corresponding position facing molybdenum target in the machine table; set the gas pressure inside the sputtering chamber between 0.05 Pa and 0.3 Pa; set the film-forming power between 50 KW and 65 KW; and set the sputtering time between 2 and 4 seconds.

After that, form a first-portion aluminum layer on the second blocking layer 241 by sputtering. Specifically, place the washed glass substrate 20 into the magnetron sputtering machine table and adjust to a position facing aluminum target in the machine table; set film-forming power between 40 KW to 70 KW; set sputtering time between 28 and 49 seconds; and set the gas pressure inside the sputtering chamber between 0.05 Pa and 0.3 Pa. After that, form a molybdenum layer (i.e. the second restraining metallic layer 244) on the first-portion aluminum layer by sputtering. Specifically, adjust the glass substrate 20 to a position facing molybdenum target in the machine table; set the gas pressure inside the sputtering chamber between 0.05 Pa and 0.3 Pa; set film-forming power between 40 KW to 70 KW; and set the sputtering time between 28 and 49 seconds. As a result, the second primary electrically conductive layer 242 having the second restraining metallic layer 244 is constructed.

After that, form the third blocking layer 243 on the second primary electrically conductive layer 242 by sputtering. Specifically, adjust the glass substrate 20 to a position facing molybdenum in the machine table; set the gas pressure inside the sputtering chamber between 0.05 Pa and 0.3 Pa; set film-forming power between 50 KW to 65 KW; and set the sputtering time between 5 and 8 seconds.

The above-mentioned second blocking layer 241, the second primary electrically conductive layer 242 and the third blocking layer 243 construct the second metallic layer 24, wherein the second primary electrically conductive layer 242 has the second restraining metallic layer 244 formed therein.

In the specific embodiment, when performing a wet etching treatment to the second metallic layer 24, because the second primary electrically conductive layer 242 has the second restraining metallic layer 244 formed therein, galvanic corrosion can be avoided between the second primary electrically conductive layer 242 and the third blocking layer 243, and thus further to ensure production stability.

In a step S504, deposit the passivation layer 25 on the second metallic layer 24, and form the through hole 251 through a center of the passivation layer 25 by etching, wherein the passivation layer 25 is preferably made of silicon nitride material.

In a step S505, form the transparent electrode layer 26 on the passivation layer 25 by using magnetron sputtering and make the transparent electrode layer 26 to connect the second metallic layer 24 via the through hole 251.

In the present invention, every time after a coating layer is formed (such as the second metallic layer 24, the passivation layer 25, etc.), there will be corresponding manufacturing processes of coating, exposure, development and etching so as to form different patterns on the corresponding coating layers, and those processes are not further discussed here.

The present invention can restrain deformation of aluminum layer under high-temperature environment by adding a restraining metallic layer (for example, a molybdenum layer) in the aluminum layer of the aluminum-and-molybdenum structure, and can also restrain the protrusion of the molybdenum layer caused by chemical reaction between the aluminum layer and the molybdenum layer, and thereby the present invention can ensure normal characteristics of the products and enhance image display quality.

The present invention has been described with a preferred embodiment thereof and it is understood that many changes and modifications to the described embodiment can be carried out without departing from the scope and the spirit of the invention that is intended to be limited only by the appended claims.

What is claimed is:

1. A thin-film transistor array substrate comprising multiple scanning lines, data lines and thin-film transistors, wherein each of the thin-film transistors includes a gate, a source and a drain; the scanning lines and the gate are formed by a first metallic layer; the data lines, the source and the drain are formed by a second metallic layer; the first metallic layer and the second metallic layer each has a multilayer structure; the multilayer structure includes a primary electrically conductive layer and at least one blocking layer, wherein:
the primary electrically conductive layer has a restraining metallic layer mounted therein and having a melting point higher than a melting point of the primary electrically conductive layer; and the restraining metallic layer has a thickness ranged between 0.5 nm and 2 nm.

2. The thin-film transistor array substrate as claimed in claim 1, wherein the primary electrically conductive layer is formed by aluminum; and the blocking layer and the restraining metallic layer are formed by molybdenum.

3. The thin-film transistor array substrate as claimed in claim 1, wherein the first metallic layer includes a first primary electrically conductive layer and a first blocking layer; the first primary electrically conductive layer has a first restraining metallic layer mounted therein; the second metallic layer includes a second blocking layer, a second primary electrically conductive layer and a third blocking layer; and the second primary electrically conductive layer has a second restraining metallic layer mounted therein.

4. A thin-film transistor array substrate comprising multiple scanning lines and data lines, wherein the scanning lines are formed by a first metallic layer, and the data lines are formed by a second metallic layer; the first metallic layer and the second metallic layer each has a multilayer structure, and the multilayer structure includes a primary electrically conductive layer and at least one blocking layer, wherein:
the primary electrically conductive layer has a restraining metallic layer mounted therein and having a melting point high than a melting point of the primary electrically conductive layer.

5. The thin-film transistor array substrate as claimed in claim 4, wherein the thin-film transistor array substrate further has a thin-film transistor; the thin-film transistor includes a gate, a source and a drain; the gate is formed by the first metallic layer; and the source and the drain are formed by the second metallic layer.

6. The thin-film transistor array substrate as claimed in claim 4, wherein the restraining metallic layer has a thickness ranged between 0.5 nm and 2 nm.

7. The thin-film transistor array substrate as claimed in claim 4, wherein the primary electrically conductive layer is formed by aluminum; and the blocking layer and the restraining metallic layer are formed by molybdenum.

8. The thin-film transistor array substrate as claimed in claim 4, wherein the first metallic layer includes a first primary electrically conductive layer and a first blocking layer; and the first primary layer has a first restraining metallic layer mounted therein;
the second metallic layer includes a second blocking layer, a second primary electrically conductive layer and a third blocking layer, and the second primary electrically conductive layer has a second restraining metallic layer mounted therein.

9. A manufacturing method of a thin-film transistor array substrate, wherein the method comprises steps of:
providing a glass substrate, forming a first metallic layer on the glass substrate and performing an etching treatment to the first metallic layer to form multiple scanning lines;
orderly depositing an insulating layer and a semiconductor layer on the first metallic layer;
forming a second metallic layer on the semiconductor layer and performing an etching treatment to the second metallic layer to form multiple data lines; and
depositing a passivation layer on the second metallic layer and forming a transparent electrode layer on the passivation layer; wherein
the first metallic layer and the second metallic layer each has a multilayer structure; the multilayer structure includes a primary electrically conductive layer and at least one blocking layer; the primary electrically conductive layer has a restraining metallic layer mounted therein and having a melting point higher than a melting point of the primary electrically conductive layer.

10. The manufacturing method of the thin-film transistor array substrate as claimed in claim 9, wherein while performing the etching treatment to the first metallic layer to form the scanning lines, also form a gate of a thin-film transistor; and
while performing the etching treatment to the second metallic layer to form the data lines, also form a source and a drain of the thin-film transistor.

11. The manufacturing method of the thin-film transistor array substrate as claimed in claim 9, wherein the step of forming the first metallic layer on the glass substrate specifically comprises steps of:
forming a first-portion aluminum layer by sputtering; forming a molybdenum layer on the first-portion aluminum layer by sputtering; forming a second-portion aluminum layer on the molybdenum layer by sputtering to construct the first metallic layer.

12. The manufacturing method of the thin-film transistor array substrate as claimed in claim 9, wherein the step of forming the second metallic layer on the semiconductor layer specifically comprises steps of:
forming a molybdenum layer on the semiconductor layer by sputtering to form a second blocking layer;
forming a first-portion aluminum layer on the second blocking layer by sputtering; forming a molybdenum layer on the first-portion aluminum layer by sputtering; forming a second-portion aluminum layer on the molybdenum layer by sputtering to construct the second primary electrically conductive layer; and
forming another molybdenum layer on the second primary electrically conductive layer by sputtering to form a third blocking layer.

13. The manufacturing method of the thin-film transistor array substrate as claimed in claim 9, wherein the restraining metallic layer has a thickness ranged between 0.5 nm and 2 nm.
